(19) United States
(12) Patent Application Publication
(10) Pub. No.: US 2025/0293512 A1
(43) Pub. Date: Sep. 18, 2025

(54) SYSTEM AND METHOD FOR PRE-CHARGE PROTECTION CIRCUIT

(71) Applicant: Rockwell Automation Technologies, Inc., Mayfield Heights, OH (US)

(72) Inventors: Jijun Cao, Shanghai (CN); Changqing Chen, Shanghai (CN); Junsheng Mu, Shanghai (CN); Jiangang Hu, Mequon, WI (US)

(21) Appl. No.: 19/077,323

(22) Filed: Mar. 12, 2025

Related U.S. Application Data
(60) Provisional application No. 63/565,061, filed on Mar. 14, 2024.

(51) Int. Cl. H02H 9/04; G01R 31/28; H02H 7/09

(52) U.S. Cl. CPC H02H 9/044; G01R 31/2879; H02H 7/09; H02H 9/045

(57) ABSTRACT

A method includes monitoring a voltage across a pre-charge circuit of a drive module disposed within an industrial automation system, wherein the pre-charge circuit is configured to reduce current flowing from a power source to a plurality of capacitors when the drive module is powered on, identifying when the voltage across the pre-charge circuit exceeds a threshold value for more than a threshold period of time, and in response to the voltage across the pre-charge circuit exceeding the threshold value for more than the threshold period of time, opening a pre-charge switch and a pre-charge bypass switch to prevent current from flowing from the power source into the pre-charge circuit and the plurality of capacitors of the drive module.

### CROSS-REFERENCE TO RELATED APPLICATIONS

This application claims priority to and the benefit of U.S. Patent Application No. 63/565,061, entitled “PRE-CHARGE PROTECTION CIRCUIT”, filed Mar. 14, 2024, which is incorporated herein by reference in its entirety for all purposes.

### BACKGROUND

The present disclosure generally relates to drive modules of industrial automation systems and, more particularly, to protecting pre-charge circuits of drive modules during fault conditions.

An industrial automation system may include a drive module to control operation of a motor. The drive module may include a pre-charge circuit to limit the inrush of current when the drive module is powered on. Once the capacitors of the drive module are charged, a pre-charge bypass switch closes to bypass the pre-charge circuit. However, when the pre-charge bypass switch is disabled (e.g., open) and the pre-charge circuit is active under fault conditions, energy may flow into the DC bus bank of the drive module, and the pre-charge circuit may fail. Accordingly, new techniques for protecting pre-charge circuits under fault conditions are needed.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, these statements are to be read in this light, and not as admissions of prior art.

### BRIEF DESCRIPTION

A summary of certain embodiments disclosed herein is set forth below. It should be understood that these aspects are presented merely to provide the reader with a brief summary of these certain embodiments and that these aspects are not intended to limit the scope of this disclosure. Indeed, this disclosure may encompass a variety of aspects that may not be set forth below.

In one embodiment, a drive module configured to control operation of a motor in an industrial automation system includes a plurality of capacitors, a pre-charge circuit, a bypass switch, and a pre-charge protection circuit. The pre-charge circuit includes one or more resistors and a pre-charge switch that electrically couples the pre-charge circuit to the plurality of capacitors. The pre-charge circuit is configured to reduce current flowing from a power source to the plurality of capacitors when the drive module is powered on. The bypass switch may include a contactor, solid switch, relay, or other semiconductor device configured to close after the plurality of capacitors are charged, bypassing the pre-charge circuit. The pre-charge protection circuit is configured to, in response to a voltage across the pre-charge circuit exceeding a threshold value for more than a threshold period of time, open the pre-charge switch and the bypass switch to prevent the current from flowing from the power source into the plurality of capacitors and the pre-charge circuit.

In another embodiment, an industrial automation system includes a motor coupled to a load, and a drive module configured to receive power from a power source and control operation of the motor. The drive module includes a plurality of capacitors, a pre-charge circuit, a bypass switch, and a pre-charge protection circuit. The pre-charge circuit includes one or more resistors and a pre-charge switch that electrically couples the pre-charge circuit to the plurality of capacitors. The pre-charge circuit is configured to reduce current flowing from the power source to the plurality of capacitors when the drive module is powered on. The bypass switch includes a contactor, solid switch, relay, or other semiconductor device configured to close after the plurality of capacitors are charged, bypassing the pre-charge circuit. The pre-charge protection circuit is configured to, in response to a voltage across the pre-charge circuit exceeding a first threshold value for more than a first threshold period of time, one or more of a plurality of respective voltages of the plurality of capacitors exceeding a second threshold value for more than a second threshold period of time, or both, open the pre-charge switch and the bypass switch to prevent the current from flowing into the plurality of capacitors and the pre-charge circuit.

In a further embodiment, a method includes monitoring a voltage across a pre-charge circuit of a drive module disposed within an industrial automation system, wherein the pre-charge circuit is configured to reduce current flowing from a power source to a plurality of capacitors when the drive module is powered on, identifying when the voltage across the pre-charge circuit exceeds a threshold value for more than a threshold period of time, and in response to the voltage across the pre-charge circuit exceeding the threshold value for more than the threshold period of time, opening a pre-charge switch and a pre-charge bypass switch to prevent current from flowing from the power source into the pre-charge circuit and the plurality of capacitors of the drive module.

Various refinements of the features noted above may exist in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended only to familiarize the reader with certain aspects and contexts of embodiments of the present disclosure without limitation to the claimed subject matter.

### BRIEF DESCRIPTION OF THE DRAWINGS

These and other features, aspects, and advantages of the present disclosure will become better understood when the following detail description is read with reference to the accompanying drawings in which like characters represent like parts throughout the drawings, wherein:

FIG. 1 illustrates an example industrial automation system employed by a food manufacturer, in accordance with an embodiment;

FIG. 2 illustrates a schematic view of a drive-motor assembly, including a drive module, of the industrial automation system of FIG. 1, in accordance with an embodiment;

FIG. 3A illustrates a first configuration of a pre-charge circuit for the drive module of FIG. 2, in accordance with an embodiment;

FIG. 3B illustrates a second configuration of a pre-charge circuit for the drive module of FIG. 2, in accordance with an embodiment;

FIG. 3C illustrates a third configuration of a pre-charge circuit for the drive module of FIG. 2, in accordance with an embodiment;

FIG. 4 illustrates a schematic of the drive module of FIG. 2 that includes one of the pre-charge circuits of FIGS. 3A-3C and a pre-charge protection circuit, in accordance with an embodiment;

FIG. 5 illustrates schematic of the various components of the pre-charge protection circuit of FIG. 4, in accordance with an embodiment;

FIG. 6 illustrates a detailed schematic of a control power circuit of the pre-charge protection circuit of FIG. 5, in accordance with an embodiment;

FIG. 7 illustrates a detailed schematic of a pre-charge input voltage sensing circuit of the pre-charge protection circuit of FIG. 5, in accordance with an embodiment;

FIG. 8 illustrates a detailed schematic of a pre-charge protection control circuit of the pre-charge protection circuit of FIG. 5, in accordance with an embodiment;

FIG. 9 illustrates a detailed schematic of the pre-charge protection control circuit of FIG. 8, a pre-charge bypass signal circuit, and an upper and lower bus capacitor overvoltage signal circuit of the pre-charge protection circuit of FIG. 5, in accordance with an embodiment;

FIG. 10 illustrates a detailed schematic of a bus capacitor voltage sensing circuit of the pre-charge protection circuit of FIG. 5, in accordance with an embodiment;

FIG. 11A illustrates a voltage plot of a simulation circuit of the pre-charge protection circuit as a function of time during a normal pre-charge, in accordance with an embodiment;

FIG. 11B illustrates a voltage plot of the simulation circuit of the pre-charge protection circuit as a function of time during a pre-charge during a fault condition, in accordance with an embodiment; and

FIG. 12 illustrates a flow chart of a process for operating the pre-charge protection circuit for the industrial automation drive module, in accordance with an embodiment.

### DETAILED DESCRIPTION

One or more specific embodiments of the present disclosure will be described below. In an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiment of the present disclosure, the articles “a,” “an,” “the,” and “said” are intended to mean that there are one or more of these elements. The terms “comprising,” “including,” and “having” are intended to be inclusive and mean that there may be additional elements other than the listed elements.

Some industrial automation systems may include one or more drive modules to control operation of a motor. The drive module may include a pre-charge circuit to limit the inrush of current to capacitors in the drive module when the drive module is powered on. Once the capacitors are charged, a pre-charge bypass switch closes such that current bypasses the pre-charge circuit. However, when the pre-charge bypass switch is disabled (e.g., open) and the pre-charge circuit is active under fault conditions, energy may flow into the DC bus bank of the drive module, causing one or more components of the drive module (e.g., the capacitors) and/or the pre-charge circuit (e.g., one or more resistors) to fail. Accordingly, new techniques for protecting pre-charge circuits under fault conditions are needed.

The present disclosure is directed to a pre-charge protection circuit that monitors a voltage across a pre-charge circuit of a drive module disposed within an industrial automation system. The pre-charge circuit is configured to reduce current flowing from a power source to a plurality of capacitors when the drive module is powered on. The pre-charge protection circuit identifies when the voltage across the pre-charge circuit exceeds a threshold value for more than a threshold period of time, and, in response to the voltage across the pre-charge circuit exceeding the threshold value for more than the threshold period of time, opens a pre-charge switch and a pre-charge bypass switch to prevent current from flowing from the power source into the pre-charge circuit and the plurality of capacitors of the drive module. In some embodiments, the pre-charge protection circuit may also be configured to monitor a plurality of respective voltages of the plurality of capacitors of the drive module, identify when one or more of the plurality of respective voltages of the plurality of capacitors exceeds a threshold value for more than a threshold period of time, and in response to the one or more of the plurality of respective voltages of the plurality of capacitors exceeding the threshold value for more than the threshold period of time, opening the pre-charge switch and the bypass switch to prevent the current from flowing from the power source into the plurality of capacitors and the pre-charge circuit.

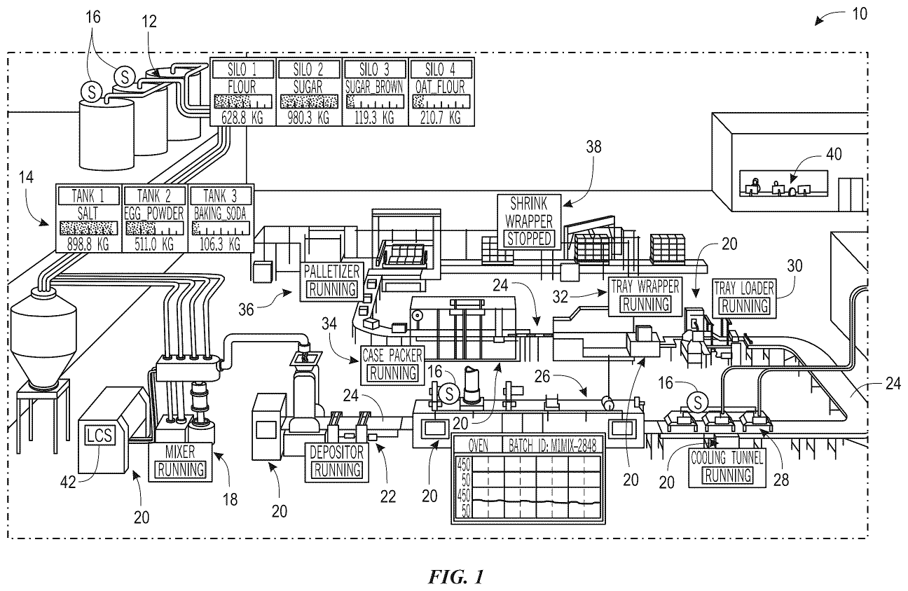

By way of introduction, FIG. 1 illustrates an example industrial automation system 10 employed by a food manufacturer in which the present embodiments described herein may be implemented. It should be noted that although the example industrial automation system 10 of FIG. 1 is directed at a food manufacturer, the present embodiments described herein may be employed within any suitable industry, such as automotive, mining, hydrocarbon production, manufacturing, and the like. That is, the following brief description of the example industrial automation system 10 employed by the food manufacturer is provided herein to help facilitate a more comprehensive understanding of how the embodiments described herein may be applied to industrial devices to significantly improve the operations of the respective industrial automation system based on the current configuration of the equipment in the industrial automation system. As such, the embodiments described herein should not be limited to be applied to the example depicted in FIG. 1.

Referring now to FIG. 1, the example industrial automation system 10 for a food manufacturer may include silos 12 and tanks 14. The silos 12 and the tanks 14 may store different types of raw material, such as grains, salt, yeast, sweeteners, flavoring agents, coloring agents, vitamins, minerals and preservatives. In some embodiments, sensors 16 may be positioned within or around the silos 12, the tanks 14, or other suitable locations within the example industrial automation system 10 to measure certain properties, such as temperature, mass, volume, pressure, humidity, and the like.

The raw materials may be provided to a mixer 18, which may mix the raw materials together according to a specified ratio. The mixer 18 and other machines in the example industrial automation system 10 may employ certain industrial automation devices 20 to control the operations of the mixer 18 and other machines. The industrial automation devices 20 may include controllers, input/output (I/O) modules, motor control centers, motors, human machine interfaces (HMIs), operator interfaces, contactors, starters, sensors 16, actuators, conveyors, drives, relays, protection devices, switchgear, compressors, sensor, actuator, firewall, network switches (e.g., Ethernet switches, modular-managed, fixed-managed, service-router, industrial, unmanaged, etc.) and the like.

The mixer 18 may provide a mixed compound to a depositor 22, which may deposit a certain amount of the mixed compound onto conveyor 24. The depositor 22 may deposit the mixed compound on the conveyor 24 according to a shape and amount that may be specified to a control system for the depositor 22. The conveyor 24 may be any suitable conveyor system that transports items to various types of machinery across the example industrial automation system 10. For example, the conveyor 24 may transport deposited material from the depositor 22 to an oven 26, which may bake the deposited material. The baked material may be transported to a cooling tunnel 28 to cool the baked material, such that the cooled material may be transported to a tray loader 30 via the conveyor 24. The tray loader 30 may include machinery that receives a certain amount of the cooled material for packaging. By way of example, the tray loader 30 may receive 25 ounces of the cooled material, which may correspond to an amount of cereal provided in a cereal box.

A tray wrapper 32 may receive a collected amount of cooled material from the tray loader 30 into a bag, which may be sealed. The tray wrapper 32 may receive the collected amount of cooled material in a bag and seal the bag using appropriate machinery. The conveyor 24 may transport the bagged material to case packer 34, which may package the bagged material into a box. The boxes may be transported to a palletizer 36, which may stack a certain number of boxes on a pallet that may be lifted using a forklift or the like. The stacked boxes may then be transported to a shrink wrapper 38, which may wrap the stacked boxes with shrink-wrap to keep the stacked boxes together while on the pallet. The shrink-wrapped boxes may then be transported to storage or the like via a forklift or other suitable transport vehicle.

To perform the operations of each of the devices in the example industrial automation system 10, the industrial automation devices 20 may be used to provide power to the machinery used to perform certain tasks, provide protection to the machinery from electrical surges, prevent injuries from occurring with human operators in the example industrial automation system 10, monitor the operations of the respective device, communicate data regarding the respective device to a supervisory control system 40, and the like. In some embodiments, each industrial automation device 20 or a group of industrial automation devices 20 may be controlled using a local control system 42. The local control system 42 may receive data regarding the operation of the respective industrial automation device 20, other industrial automation devices 20, user inputs, and other suitable inputs to control the operations of the respective industrial automation device(s) 20.

The local control system 42 may have access to configuration data associated with the connected industrial automation devices 20. That is, the local control system 42 may include memory or a storage component that stores information concerning the configuration of each industrial automation device 20 connected to it. In some embodiments, the information or configuration data may be populated or input by an operator at the time the respective industrial automation device 20 is installed. Additionally, the local control system 42 may query the connected industrial automation device 20 to retrieve configuration data, such as model number, serial number, firmware revision, assembly profile, and the like. In some embodiments, the supervisory control system 40 may collect configuration data from multiple local control systems 40 and store the information in a suitable memory or storage component.

In some embodiments, the industrial automation devices 20 of the example industrial automation system 10 may include one or more drives to control one or more motors. Each drive may include a control system for controlling the one or more motors. In some embodiments, the local control system 42 may transmit command signals to one or more drive control systems, which, in turn, enables the movement of the one or more motors.

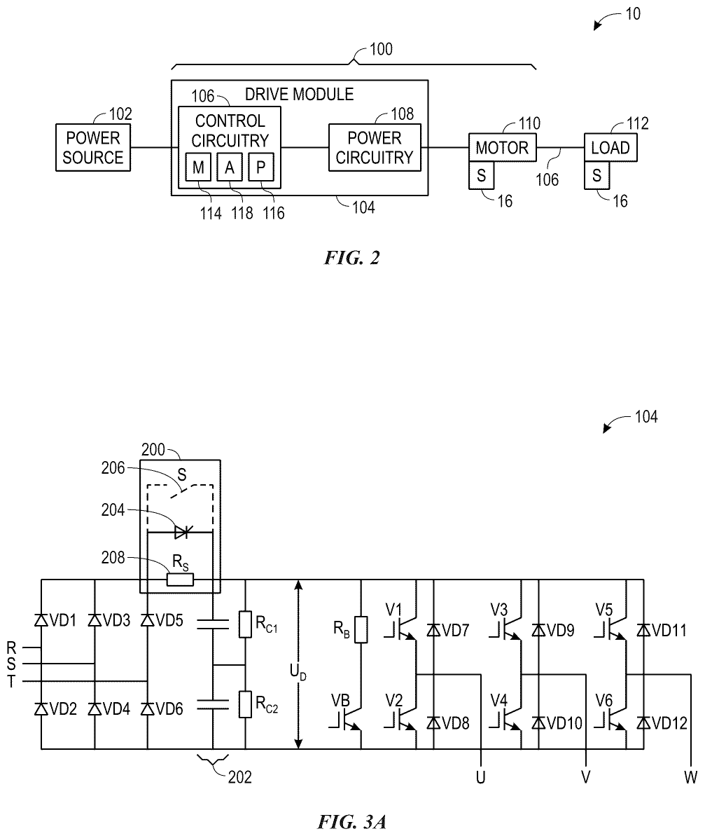

FIG. 2 is a schematic view of a drive-motor assembly 100 of the industrial automation system 10 of FIG. 1. The industrial automation system 10 may include a power source 102, a drive module 104, which includes control circuitry 106 (e.g., a controller board) and power circuitry 108 (e.g., a power board), a motor 110, and a load 112. The control circuitry 106, which may be used to control operations of the drive module 104, may include various subcomponents, such as a non-transitory memory 114, processing circuitry 116, an accelerometer 118, a user interface, and the like. The drive module 104 may also include various subcomponents, such as a rectifier, an inverter, driver circuitry, one or more switches, etc., that may be used to control the operation of the motor 110. In the instant embodiment, the industrial automation system 10 may include one or more drive modules 104 coupled to respective motors 110, which are then coupled to one or more loads 112 via a connection 120 (e.g. drive shaft, chain, etc.).

In some cases, the motor 110 (or some component associated with the motor) may be provided with an encoder 16 or a similar device to provide feedback data to the drive module 104. The encoder measures the angular position of the drive shaft, from which velocity and acceleration data may be derived, to provide the feedback data to the drive module 104. In certain motors and associated control circuitry, this information may be estimated for “sensorless” control. Where such information is measured or estimated, the system may be controlled to implement a closed-loop velocity control regime, a torque-control regime, or other known techniques to track the desired motion and/or load profile of the application. For example, the drive module 104 may adjust the power output to the motor 110 (e.g., the frequency of the drive signals), thereby controlling its speed, based on the signal from the encoder 16.

The power circuitry 108 may be designed for any suitable power rating. The power circuitry 108 may receive three-phase power and output three-phase power for operation of the motor 110. For example, the power circuitry 108 may include any number of components, such as inverters, converters, switches, DC capacitor banks, and so forth that may receive three-phase AC power, may rectify the three-phase AC power to DC power (e.g., a DC voltage waveform), and may invert and may generate a three-phase output AC power waveform at a desired frequency for actuating the motor 110 connected to the drive module 104. Moreover, the power circuitry 108 may be configured to condition the power signal output. For example, the power circuitry 108 converts a signal from alternating current (AC) to direct current (DC), converts a signal from DC to AC, step a signal up, step a signal down, and the like. In some cases, the processor 116 of the control circuitry 106 may control switching frequency or firing angles of one or more switching devices (e.g., IGBTs, transistors) that are disposed on the power circuitry 108. The changes to switching frequency may adjust or modify the AC voltage waveforms, phase shifts between the AC voltage waveforms, and other properties associated with the AC voltage waveforms provided to the motor 110 within a motor housing.

The power source 102 may supply a regular voltage or high voltage AC signal provided by a utility power grid (e.g., a standard electrical outlet), a battery, a capacitor, a generator, or some other source of AC or DC electrical power. However, it should be understood that many possible embodiments are envisaged. For example, the control circuitry 106 may include various components that may output one or more control signals (directly or indirectly) to the motor 110 or actuator to cause the motor to operate. For example, the motor may operate to move (e.g., spin, rotate, etc.) a shaft 120. The processor 116 of the control circuitry 106 may provide the control signals based on data acquired from the accelerometer 118, the non-transitory memory 114, or both.

The motor 110 may have mechanical and/or electrical components and may include a linear motor, a servo, a rotational electric motor, a combustion engine, a trolley, a mover, or any other component configured to move in response to a control signal. The motor 110 may be disposed within a separate housing (e.g., the motor housing) as compared to the drive module 104, such that the two housings may be coupled directly to each other or via an adapter module or housing element. The load 112 may be any load that is moved by the motor 110. In some embodiments, sensors 16 may be disposed on the motor 110, on the load 112, or both. The sensors 16 may be in communication with the control circuitry 106 (e.g., the processor 116) of the drive module 104. For example, the control circuitry 106 may generate the control signals based on receiving the measurements from the sensors 16.

The drive module 104 may include circuitry designed for starting, driving, braking, actuating, and performing any other suitable control operations for the motor 110. The circuitry may be designed for any suitable power rating, often referred to by the frame size, of the motor. For example, the processor 116 of the control circuitry 106 may monitor functions and coordinate operations of the motor 110. The drive module 104 and the motor 110 may communicate using a network connection according to any suitable connection protocol, such as standard industrial protocols, Ethernet protocols, Internet protocols, wireless protocols, and so forth. In some embodiments, the drive module 104 may be a variable speed drive (VSD) or variable frequency drive (VFD).

The processor 116 typically carries out predefined control routines, or those defined by an operator, based upon parameters set during commissioning of the equipment and/or parameters sensed and fed back to the control circuitry 106 during operation of the motor 110. The control circuitry 106 may include an interface to transfer control, feedback, and other signals to the motor 110 and/or external devices. Many different control schemes and functions may be implemented by the control circuitry 106. Programs for some of the operations may be stored on a non-transitory computer-readable medium (e.g., the non-transitory memory 114).

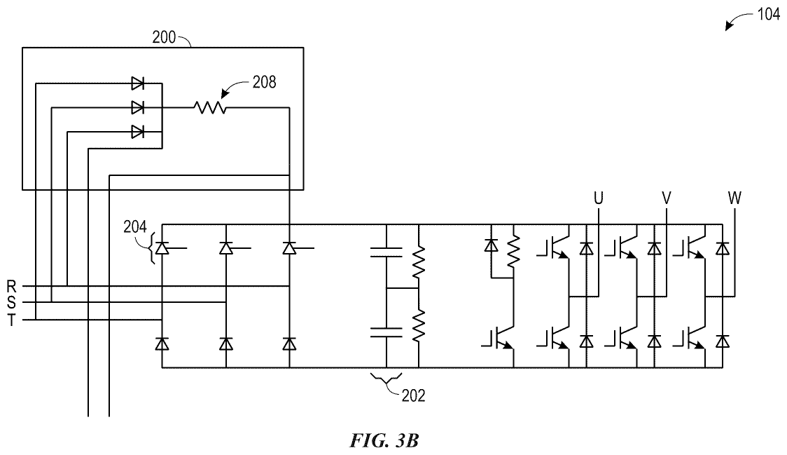

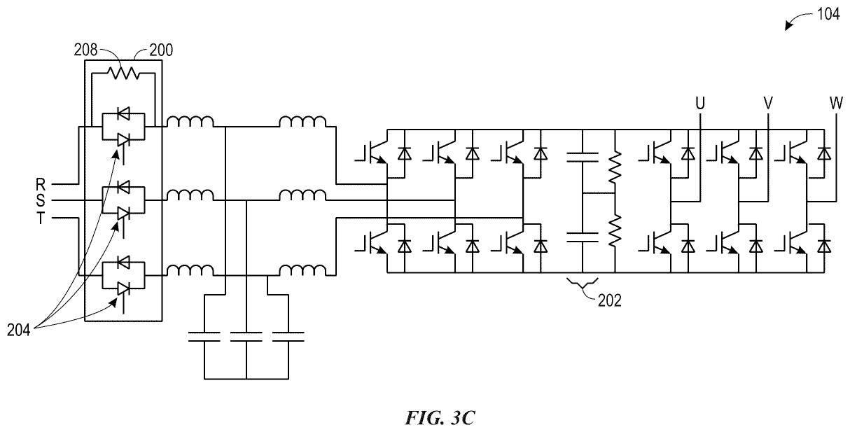

Some drive modules 104 may be equipped with a pre-charge circuit configured to limit the inrush of current when the drive module 104 is powered on. FIGS. 3A-3C illustrate three different configurations of pre-charge circuits 200. When the drive module 104 is powered on, the capacitors 202 in the DC bus are initially uncharged and act like a short circuit, resulting in an inrush in current. Accordingly, the pre-charge circuit 200 limits the inrush of current while the capacitors 202 charge, such that the current flows in a controlled manner until the voltage level approaches or reaches the voltage level of the power source, thus preventing damage to components, such as capacitors, connectors, cables, fuses, and so forth. Once the capacitors 202 are charged, a contactor bypasses the pre-charge circuit 200.

In the embodiment of the pre-charge circuit 200 shown in FIG. 3A, a silicon-controlled rectifier (SCR) 204 or a relay contact 206 is in parallel with one or more resistors 208. The SCR 204 and/or relay contact 206 are open, such that current flows through the resistors 208, reducing the inrush of current, until the capacitors 202 in the DC bus are charged. Once the capacitors 202 are charged, the SCR 204 and/or the relay contact 206 closes to bypass the resistors 208 and allow current to flow to the capacitors 202, bypassing the pre-charge circuit 200.

In the embodiment of the pre-charge circuit 200 shown in FIG. 3B, three SCRs 204 are in parallel with one another and in parallel with one or more resistors 208. The SCRs 204 are open, such that current flows through the resistors 208, reducing the inrush of current, until the capacitors 202 in the DC bus are charged. Once the capacitors 202 are charged, the SCRs 204 close to bypass the resistors 208 and allow current to flow to the capacitors 202, bypassing the pre-charge circuit 200.

In the embodiment of the pre-charge circuit 200 shown in FIG. 3C, three pair of SCRs/diodes 204 are in parallel with one another, and in parallel with one or more resistors 208. The SCRs 204 are open, such that current flows through the resistors 208, reducing the inrush of current, until the capacitors 202 in the DC bus are charged. Once the capacitors 202 are charged, the SCRs 204 close to bypass the resistors 208 and allow current to flow to the capacitors 202, bypassing the pre-charge circuit 200.

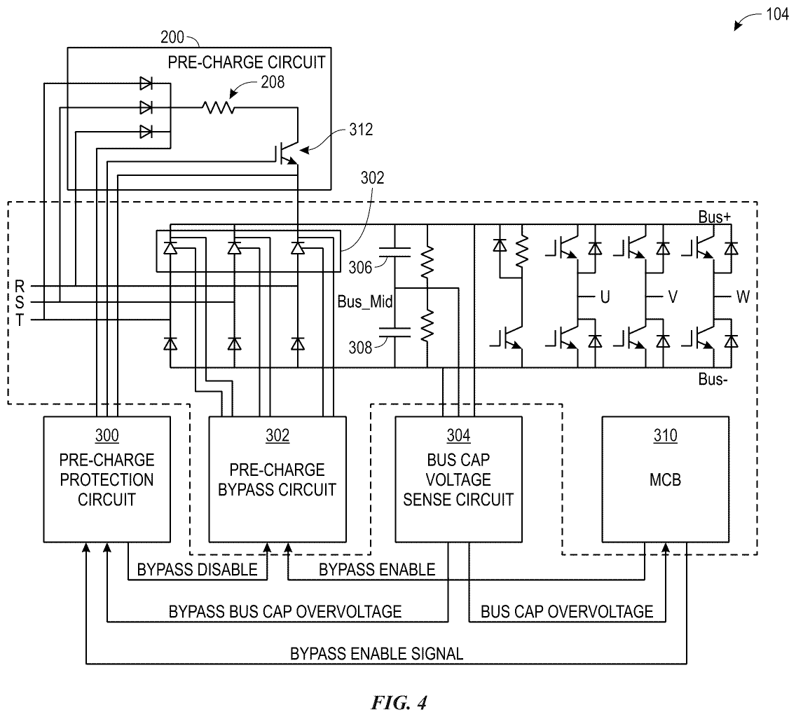

For drive modules 104 with pre-charge circuits 200, when the bypass switch is disabled (e.g., open) and the pre-charge circuit 200 is active under fault conditions, energy may flow into the DC bus bank, and the pre-charge circuit 200 may fail. This may occur, for example, when the DC bus is shorted (e.g., external or internal faults) during power up, breakdown of component test (BOC test) after bus capacitor failure (e.g., upper leg, lower leg, underwriters laboratories (UL) test, etc.), DC bus of drive module 104 overload during power up, unbalances bus or failed bus balance circuit, pre-charge failures during normal operation with a long cable, and so forth. Accordingly, FIG. 4 illustrates a schematic of a drive module 104 that includes a pre-charge circuit 200 and a pre-charge protection circuit 300.

A pre-charge switch 312 is connected in series with the pre-charge resistors 208 and operates based on signals from the pre-charge protection circuit 300 and a main control board (MCB) 310, which may be the same as the processor 116 shown in FIG. 2. During power up of the drive module 104, the time to pre-charge the drive module 104 exceeding a threshold amount of time may be indicative of a fault. Accordingly, when the time to pre-charge exceeds the threshold amount of time, the pre-charge protection circuit 300 may determine that a fault is present and open the pre-charge switch 312, preventing power from flowing to the main circuit switches, such that no power flows to the drive module 104 the main circuit and/or the pre-charge circuit 200. The pre-charge switch 312 remains open until the fault condition is resolved and the drive module 104 is to be powered up again. Further, the pre-charge protection circuit 300 may be configured to use a bus capacitor (“bus cap”) voltage monitoring sensing circuit 304 to monitor voltages of the bus cap bank legs 306, 308 to identify faulted bus conditions and send signals to both the pre-charge bypass circuit 302 and the pre-charge circuit 200 to open the pre-charge bypass switch 302 and pre-charge switch 312.

The pre-charge protection circuit 300 draws power from the voltage between the inputs and outputs of the pre-charge circuit 200. The pre-charge protection circuit 300 monitors the voltage across the inputs and outputs of the pre-charge circuit 200 and when the voltage is greater than a threshold value for more than a threshold amount of time, or the pre-charge protection circuit 300 receives a signal from the MCB 310, the pre-charge protection circuit 300 opens the pre-charge switch 312 in the pre-charge circuit 200, At the same time, the pre-charge protection circuit 300 sends a signal to disable the pre-charge bypass switch 302. The pre-charge protection circuit 300 may also receive a signal from the bus cap voltage sensing circuit 304 when the bus cap voltage exceeds a threshold voltage or is unbalanced. In response, the pre-charge protection circuit 300 may open the pre-charge switch 312 and send signals to pre-charge bypass circuit 302. Further, when the pre-charge bypass circuit 302 receives the signal, the pre-charge bypass circuit 302 opens its switch. When both the pre-charge bypass switch 302 and the pre-charge switch 312 are open, no energy flows into the cap bank 306, 308. When the voltage of the cap bank 306, 308, as measured by the bus cap voltage sensing circuit 304, drops below the threshold value, the bus cap voltage sensing circuit 304 resets its output signals and energy flows into the cap bank 306, 308 via the pre-charge circuit 200, which supports the MCB 310.

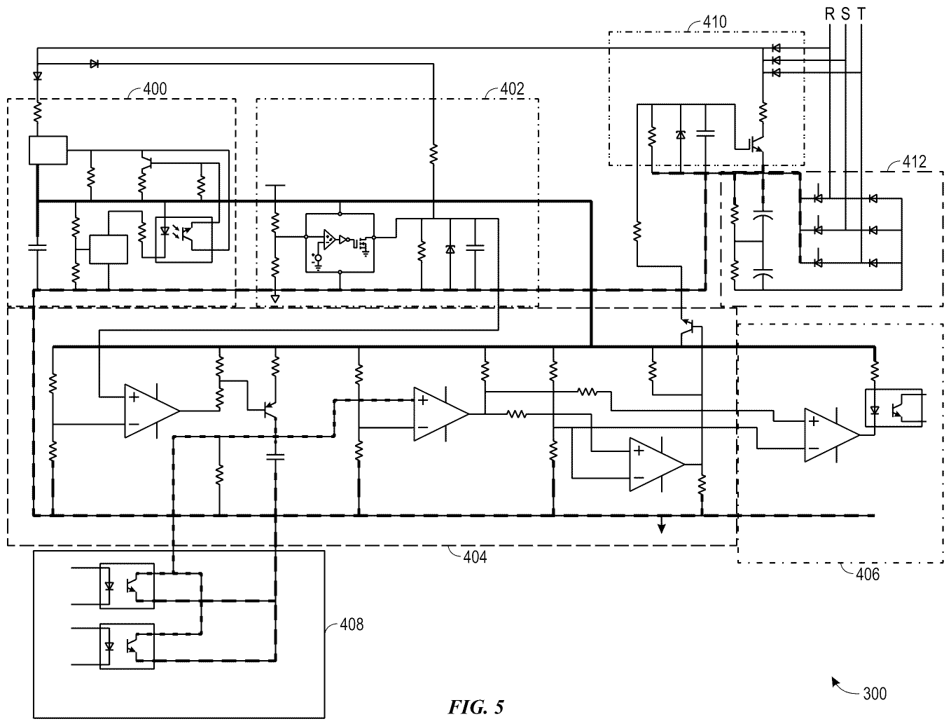

FIG. 5 is a schematic of the various components of the pre-charge protection circuit 300, which will each be described in more detail below. Specifically, the pre-charge protection circuit 300 includes a control power circuit 400, a pre-charge input voltage sensing circuit 402, a pre-charge protection control circuit 404, a pre-charge bypass control circuit 406, a bus cap overvoltage sensing circuit 408, a gating circuit 410 for the pre-charge switch. Circuit 412 is part of the drive's main power circuit, which includes the bypass switch (main rectifier circuit) and main electrolytic capacitor bank, circuit 412 is coupled to the output of pre-charge circuit as shown in FIG. 5. The control power circuit 400 is configured to receive an input voltage and provide power to the pre-charge protection circuit 300 based on the input voltage. The pre-charge input voltage sensing circuit 402 is configured to output a signal indicative of a voltage across the pre-charge circuit, wherein the voltage across the pre-charge circuit indicates a difference between the input voltage to the pre-charge circuit and an output voltage of the pre-charge circuit. The pre-charge protection control circuit 404 is configured to receive, from the pre-charge input voltage sensing circuit, the signal indicative of the voltage across the pre-charge circuit. In response to the voltage across the pre-charge circuit being below the threshold value, the pre-charge protection control circuit 404 outputs a second signal to allow the current to flow from the power source into one or more of the plurality of capacitors. In response to the voltage across the pre-charge circuit being above the threshold value for longer than a threshold time interval, the pre-charge protection control circuit 404 outputs a third signal to prevent the current from flowing from the power source into the one or more of the plurality of capacitors. The pre-charge bypass control circuit 406 is configured to generate a signal to control the pre-charge bypass switch. The bus cap overvoltage sensing circuit 408 is configured to receive the first signal from the capacitor voltage sensing circuit and output a third signal to open the pre-charge switch and the bypass switch to prevent the current from flowing from the power source into the plurality of capacitors and the pre-charge circuit in response to the one or more of the plurality of voltages of the plurality of capacitors exceeding the additional threshold value for more than the additional threshold period of time. The gating circuit 410 for the pre-charge switch is configured to output a signal to control the pre-charge switch.

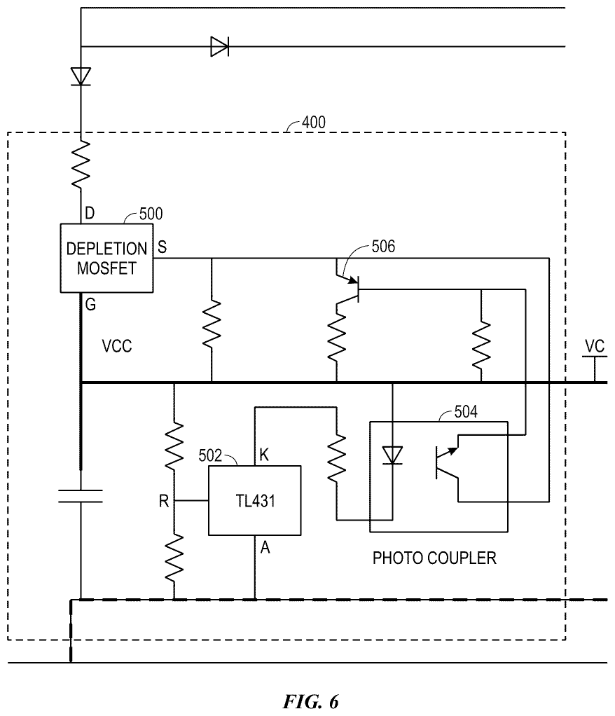

FIG. 6 is a detailed schematic of the control power circuit 400. The control power circuit 400 includes a depletion mosfet 500 to provide a controlled current source. When the voltage between the S and G terminals is larger (e.g., greater than a threshold or greater than a reference voltage), the current through the D terminal is small. Correspondingly, when the voltage between the S and G terminals is smaller (e.g., less than a threshold or less than a reference voltage), the current through the D terminal is maximum. The control power circuit 400 also includes a three-terminal voltage regulator 502 (e.g., TL431). When the voltage at the common collector (VCC, determined by the resistors connected to the R input of the three-terminal voltage regulator 502) is below the setting (e.g., threshold) value, a photo coupler 504 opens its output, causing a transistor 506 to turn on, causing the voltage between the S and G terminals of the depletion mosfet 500 to be minimal or zero, the current through the depletion mosfet 500 to be maximum, and the VCC to increase. Correspondingly, when the VCC is greater that the setting (e.g., threshold) value, the photo coupler 504 closes its output, causing the transistor 506 to turn off, the voltage between the S and G terminals of the depletion mosfet 500 to be at a maximum with a small or no amount of current flowing, the current through the depletion mosfet 500 to be at a minimum or zero, and the VCC decreases, dynamically adjusting its output current to adjust the VCC voltage.

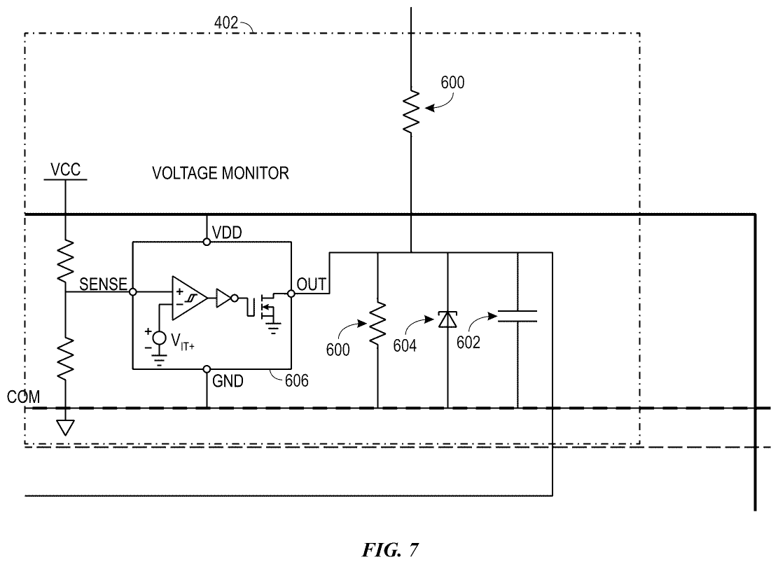

FIG. 7 is a detailed schematic of the pre-charge input voltage sensing circuit 402, which is used to measure the voltage between the pre-charge circuit input and the pre-charge circuit output. The pre-charge input voltage sensing circuit 402 includes dividend resistors 600, filter capacitors 602, zender diodes 604, and a voltage monitor integrated circuit (IC) 606. The zender diode 604 is used to limit the output voltage of the pre-charge input voltage sensing circuit 402. The voltage monitor IC 606 monitors the VCC. When the VCC is lower than a reference or threshold voltage, the output of the pre-charge input voltage sensing circuit 402 will also be low, preventing generation of errant logic when the VCC has not reached steady state. The filter cap 602 is used to filter the noise signal of the input voltage.

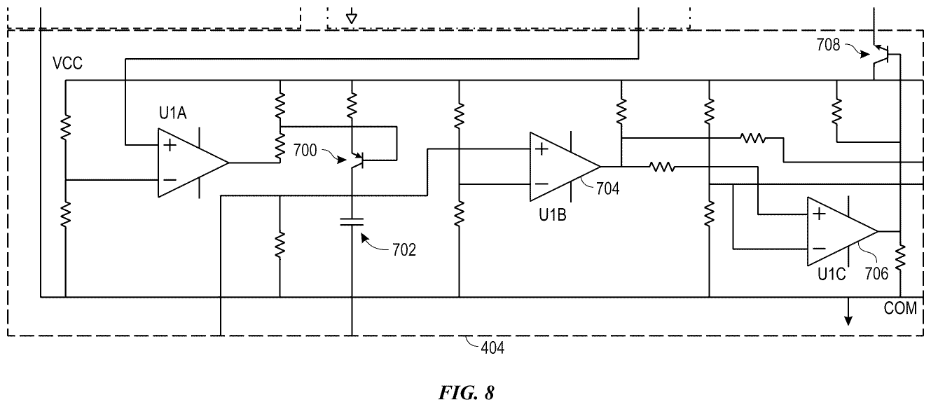

FIG. 8 is a detailed schematic of the pre-charge protection control circuit 404, which is used to protect pre-charge resistors. When the voltage across the pre-charge input and output is greater than a threshold value, a first transistor 700 is disabled, such that no current flows to a capacitor 702. The capacitor 702 will be discharged by the resistors. Once voltage across the pre-charge input and output is higher than the threshold value for more than a preset time, a first comparator 704 will output low and a second comparator 706 will output low, and the second transistor 708 will disable the pre-charge switch in the gating circuit for the pre-charge switch 410 (not shown). When the voltage across the pre-charge input and output is less than the threshold value, the first transistor 700 will be activated, causing current to flow into the first capacitor 702, which will have an elevated voltage. The first comparator 704 will output high and the second comparator 706 will output high, enabling the pre-charge switch in the gating circuit for the pre-charge switch 410 (not shown). If the input voltage is above the threshold, but for less than a threshold period of time, the pre-charge protection control circuit 404 enables the pre-charge switch in the gating circuit for the pre-charge switch 410 (not shown).

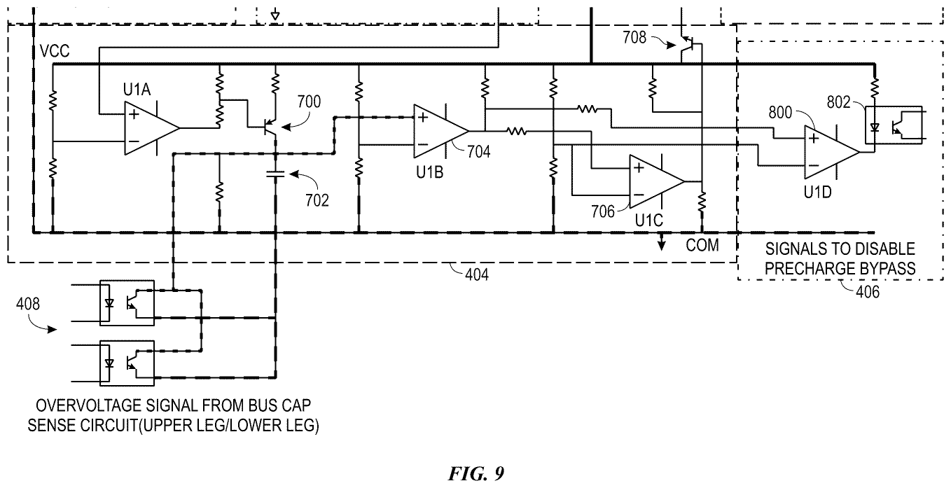

FIG. 9 is a detailed schematic of the pre-charge protection control circuit 404, the pre-charge bypass signal circuit 406, and the upper and lower bus cap overvoltage signal circuit 408. When the pre-charge switch in the gating circuit for the pre-charge switch 410 (not shown) is disabled, the logic signals are sent to a third comparator 800, which outputs a low voltage level, causing the input of a photo coupler 802 to be conductive, and the output of the photo coupler 802 to be low. The output of the photo coupler 802 may be output and used to disable signals of the pre-charge bypass 302 (not shown). In some embodiments, the output may also be provided as an input to the MCB 310 (not shown) to inform the pre-charge protection control circuit 404 that the MCB 310 is not working properly.

The bus cap overvoltage signal is received from the bus cap over voltage sensing circuit 304 (not shown) and can directly disable the mosfet until the bus cap voltage reaches steady state or an expected value. Because the bus cap voltage sensing circuit 304 has a hysteresis voltage, if the delta voltage is larger than a threshold amount, the upper and lower bus cap overvoltage signal circuit 408 may generate a signal to trigger input voltage protection, which will prevent power from flowing to the drive module until a subsequent power up.

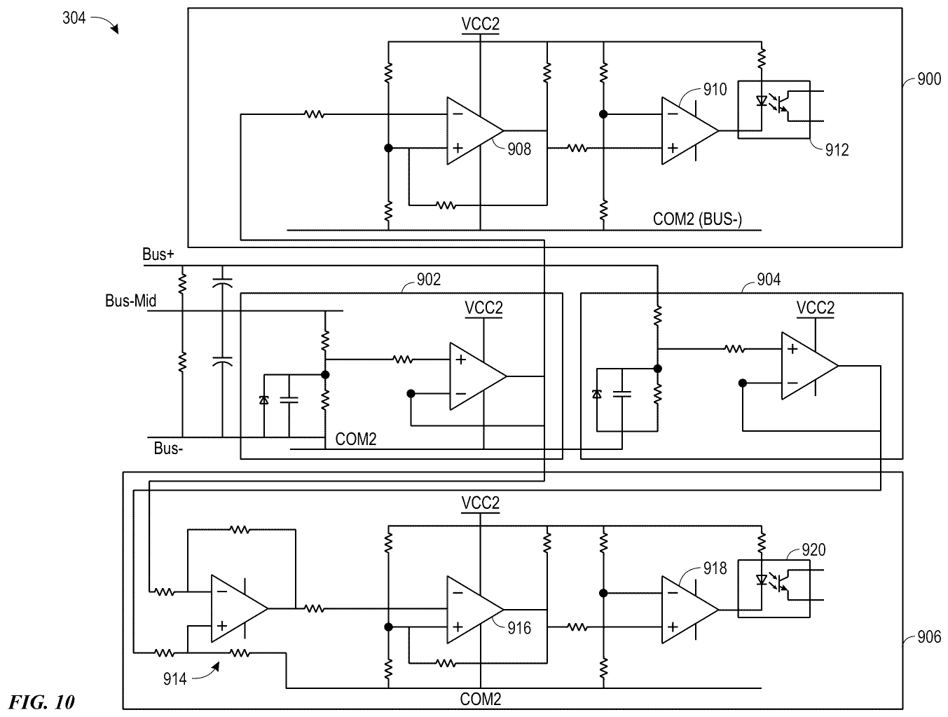

FIG. 10 is a schematic of the bus cap voltage sensing circuit 304. As shown, the bus cap voltage sensing circuit 304 includes a lower cap overvoltage sensing circuit 900, a lower cap voltage sampling circuit 902, a positive bus voltage sampling circuit 904, and an upper cap over voltage sensing circuit 906. The lower cap overvoltage sensing circuit 900 includes a first comparator 908, a second comparator 910, and a photo coupler 912. If the voltage at the input of sampling circuit 902 (e.g., the lower cap voltage) is greater than a first threshold voltage, the photo coupler 912 output is low. When the voltage at the input of sampling circuit 902 (e.g., the lower cap voltage) is less than a second threshold, the photo coupler 912 output is high. The difference between the first threshold and the second threshold is the hysteresis voltage at which the lower cap overvoltage sensing circuit 900 changes state.

The lower cap voltage sampling circuit 902 is configured to sample the mid bus voltage. Correspondingly, the positive bus voltage sampling circuit 904 is configured to sample the positive bus voltage.

The upper cap over voltage sensing circuit 906 includes a difference circuit 914 configured to take the difference between the outputs of the lower cap voltage sampling circuit 902 and the positive bus voltage sampling circuit 904 to determine the upper cap voltage. Further, the upper cap over voltage sensing circuit 906 includes a first comparator 916, a second comparator 918, and a photo coupler 920 that receive the upper cap voltage from the difference circuit 914. If the voltage at the difference circuit output of 914 (e.g., the upper cap voltage) is greater than a first threshold voltage, the photo coupler 920 output is low. When the voltage at the input of difference circuit output of 914 (e.g., the upper cap voltage) is less than a second threshold, the photo coupler 920 output is high. The difference between the first threshold and the second threshold is the hysteresis voltage at which the upper cap overvoltage sensing circuit 906 changes state.

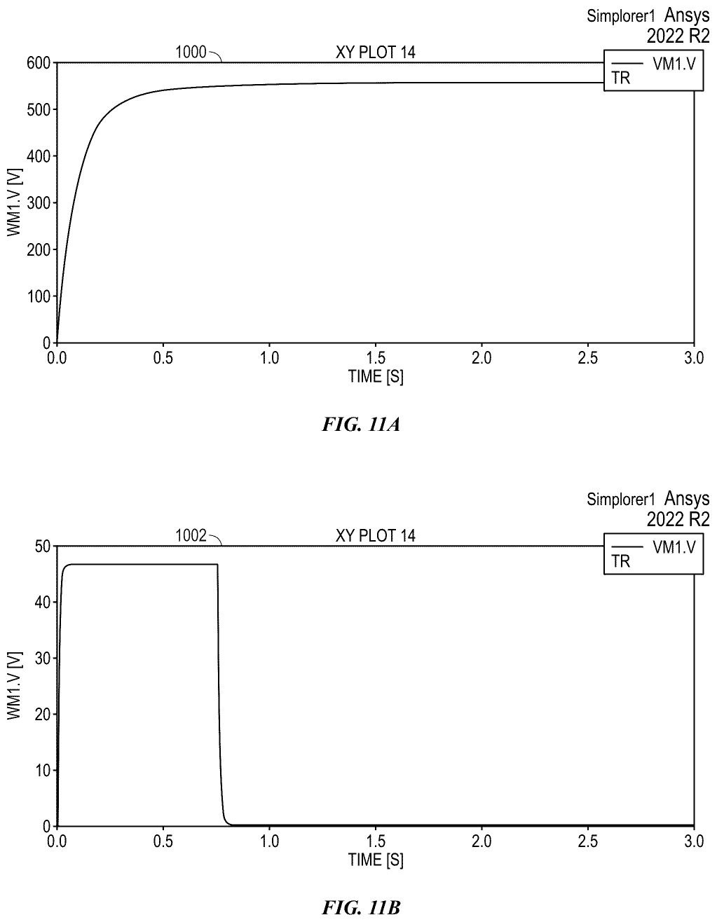

FIGS. 11A and 11B illustrate voltage plots 1000, 1002 of a simulation circuit of the pre-charge protection circuit as a function of time. Plot 1000 illustrates a normal pre-charge. As shown, the voltage starts at zero and then increases as the voltage reaches a steady state operating voltage, at which point the drive module is pre-charged. In the embodiment shown in FIGS. 11A and 11B, the pre-charge circuit includes 20-ohm pre-charge resistors. It should be understood, however, that embodiments of the pre-charge circuit having resistors of different values are also envisaged. Plot 1002 illustrates the pre-charge protection circuit activating when the DC bus is shorted with 2-ohm resistors. As shown, the DC bus voltage increases and keeps at a low voltage level due to the short circuit. After some time, the pre-charge protecting circuit activates to protect the pre-charge resistors and the drive module, causing the voltage to quickly fall back down to zero.

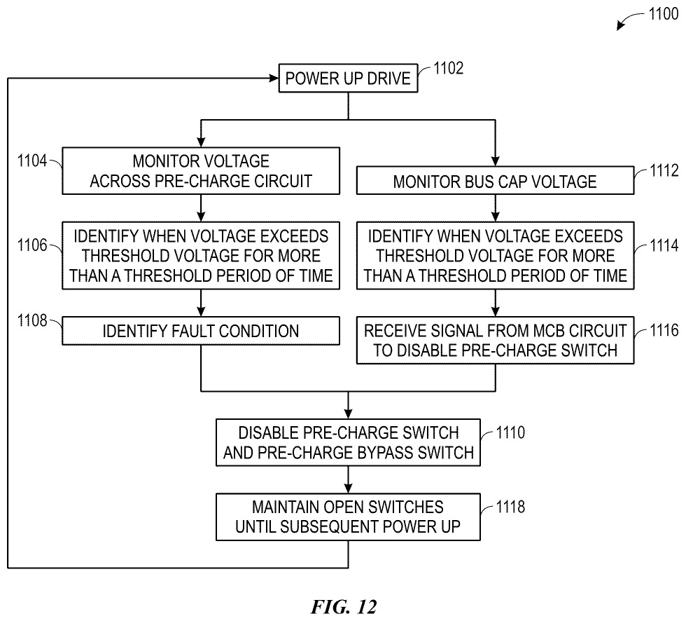

FIG. 12 is a flow chart of a process 1100 for operating a pre-charge protection circuit for an industrial automation drive module. At 1102, the drive module having a pre-charge circuit and a pre-charge protection circuit is powered up. The drive module may be powered up based on a command (e.g., a manual input, a remote command, etc.), according to a schedule, in response to some triggering event or condition being detected, and the like. As previously described, the pre-charge circuit limits the inrush of current while the capacitors charge, such that the current flows in a controlled manner until the voltage level reaches the voltage level of the power source, thus preventing damage to components (e.g., capacitors, connectors, cables, fuses, etc.). Once the capacitors are charged, a contactor, solid switch, relay, or other semiconductor device, closes to bypass the pre-charge circuit. Further, the pre-charge protection circuit may be configured to identify when faults are present and opens one or more switches to prevent power from flowing to the pre-charge circuit and the drive to prevent damage to the various components of the pre-charge circuit and the drive.

At 1104, the process 1100 monitors the voltage across the pre-charge circuit. At 1106, the process 1100 identifies when the voltage across the pre-charge circuit exceeds a threshold voltage for more than a threshold amount of time. When the voltage across the pre-charge circuit exceeds the threshold voltage for more than the threshold amount of time, the process 1100 identifies that a fault condition is present (at block 1108). In response, at 1110, the process 1100 disables the pre-charge switch and the pre-charge bypass switch, such that no power can flow into the pre-charge circuit or the drive.

Further, at 1112, the process 1100 monitors the bus cap voltage of the drive. At 1114, the process 1100 identifies when the bus cap voltage exceeds another threshold voltage for more than another threshold amount of time. When the bus cap voltage exceeds the threshold voltage for more than the threshold amount of time, the process 1100, at 1116, receives a signal from the MCB to disable the pre-charge switch. In response, at 1110, the process 1100 disables the pre- charge switch and the pre-charge bypass switch, such that no power can flow into the pre-charge circuit or the drive. At 1118, the process 1100 maintains the open switches until subsequent power up of the drive at 1102.

The present disclosure is directed to a pre-charge protection circuit that monitors a voltage across a pre-charge circuit of a drive module disposed within an industrial automation system. The pre-charge circuit is configured to reduce current flowing from a power source to a plurality of capacitors when the drive module is powered on. The pre-charge protection circuit identifies when the voltage across the pre-charge circuit exceeds a threshold value for more than a threshold period of time, and, in response to the voltage across the pre-charge circuit exceeding the threshold value for more than the threshold period of time, opens a pre-charge switch and a pre-charge bypass switch to prevent current from flowing from the power source into the pre-charge circuit and the plurality of capacitors of the drive module. In some embodiments, the pre-charge protection circuit may also be configured to monitor a plurality of respective voltages of the plurality of capacitors of the drive module, identify when one or more of the plurality of respective voltages of the plurality of capacitors exceeds a threshold value for more than a threshold period of time, and in response to the one or more of the plurality of respective voltages of the plurality of capacitors exceeding the threshold value for more than the threshold period of time, opening the pre-charge switch and the bypass switch to prevent the current from flowing from the power source into the plurality of capacitors and the pre-charge circuit. Use of the disclosed techniques may protect various components of the pre-charge circuit and the drive module during fault conditions, such that the drive module can survive fault conditions without component failure, thus resulting in less down time, fewer failed components to be replaced, and more resilient drive modules.

While only certain features of the present disclosure have been illustrated and described herein, many modifications and changes will occur to those skilled in the art. It is therefore, to be understood that the appended claims are intended to cover all such modifications and changes as fall within the true spirit of the embodiments described herein.

The techniques presented and claimed herein are referenced and applied to material objects and concrete examples of a practical nature that demonstrably improve the present technical field and, as such, are not abstract, intangible or purely theoretical. Further, if any claims appended to the end of this specification contain one or more elements designated as “means for [perform]ing [a function]. . .” or “step for [perform]ing [a function]. . . ,” it is intended that such elements are to be interpreted under 35 U.S.C. 112(f). However, for any claims containing elements designated in any other manner. it is intended that such elements are not to be interpreted under 35 U.S.C. 112(f).

1. A drive module configured to control operation of a motor in an industrial automation system, the drive module comprising:
a plurality of capacitors;
a pre-charge circuit comprising one or more resistors and a pre-charge switch that electrically couples the pre-charge circuit to the plurality of capacitors, wherein the pre-charge circuit is configured to reduce current flowing from a power source to the plurality of capacitors when the drive module is powered on;
a bypass switch comprising a contactor, solid switch, relay, or any combination thereof, configured to close after the plurality of capacitors are charged, bypassing the pre-charge circuit; and
a pre-charge protection circuit configured to, in response to a voltage across the pre-charge circuit exceeding a threshold value for more than a threshold period of time, open the pre-charge switch and the bypass switch to prevent the current from flowing from the power source into the plurality of capacitors and the pre-charge circuit.

2. The drive module of claim 1, wherein the pre-charge protection circuit is configured to, in response to one or more of a plurality of respective voltages of the plurality of capacitors exceeding an additional threshold value for more than an additional threshold period of time, open the pre-charge switch and the bypass switch to prevent the current from flowing into the plurality of capacitors and the pre-charge circuit.

3. The drive module of claim 2, wherein the one or more of the plurality of respective voltages of the plurality of capacitors exceeding the additional threshold value for more than the additional threshold period of time is indicative of a fault within the drive module.

4. The drive module of claim 2, wherein the drive module comprises:
a capacitor voltage sensing circuit configured to monitor the plurality of respective voltages of the plurality of capacitors and output a first signal indicative of one or more of the plurality of respective voltages of the plurality of capacitors; and
a main control board configured to receive the first signal and provide a second signal to the pre-charge protection circuit to open the pre-charge switch and the bypass switch to prevent the current from flowing from the power source into the plurality of capacitors and the pre-charge circuit in response to the one or more of the plurality of respective voltages of the plurality of capacitors exceeding the additional threshold value for more than the additional threshold period of time.

5. The drive module of claim 4, wherein the pre-charge protection circuit comprises a capacitor overvoltage signal circuit configured to:
receive the first signal from the capacitor voltage sensing circuit; and
output a third signal to open the pre-charge switch and the bypass switch to prevent the current from flowing from the power source into the plurality of capacitors and the pre-charge circuit in response to the one or more of the plurality of respective voltages of the plurality of capacitors exceeding the additional threshold value for more than the additional threshold period of time.

6. The drive module of claim 1, wherein the pre-charge protection circuit comprises a control power circuit configured to receive an input voltage and provide power to the pre-charge protection circuit based on the input voltage.

7. The drive module of claim 6, wherein the pre-charge protection circuit comprises a pre-charge input voltage sensing circuit configured to output a signal indicative of a voltage across the pre-charge circuit, wherein the voltage across the pre-charge circuit comprises a difference between the input voltage to the pre-charge circuit and an output voltage of the pre-charge circuit.

8. The drive module of claim 7, wherein the pre-charge protection circuit comprises a pre-charge protection control circuit configured to:
receive, from the pre-charge input voltage sensing circuit, the signal indicative of the voltage across the pre-charge circuit;
in response to the voltage across the pre-charge circuit being below the threshold value, outputting a second signal to allow the current to flow from the power source into one or more of the plurality of capacitors; and
in response to the voltage across the pre-charge circuit being above the threshold value for more than a further threshold period of time, outputting a third signal to prevent the current from flowing from the power source into the one or more of the plurality of capacitors.

9. The drive module of claim 8, wherein the pre-charge protection circuit comprises a pre-charge bypass signal circuit configured to:
receive the second and third signals from the pre-charge protection control circuit; and
output a fourth signal to enable or disable the bypass switch based on receiving the second signal or the third signal.

10. The drive module of claim 1, wherein the pre-charge protection circuit comprises a gating circuit configured to control the pre-charge switch.

11. An industrial automation system, comprising:
a motor coupled to a load; and
a drive module configured to receive power from a power source and control operation of the motor, wherein the drive module comprises:
a plurality of capacitors;
a pre-charge circuit comprising one or more resistors and a pre-charge switch that electrically couples the pre-charge circuit to the plurality of capacitors, wherein the pre-charge circuit is configured to reduce current flowing from the power source to the plurality of capacitors when the drive module is powered on;
a bypass switch comprising a contactor, solid switch, relay, or any combination thereof, configured to close after the plurality of capacitors are charged, bypassing the pre-charge circuit; and
a pre-charge protection circuit configured to, in response to a voltage across the pre-charge circuit exceeding a first threshold value for more than a first threshold period of time, one or more of a plurality of respective voltages of the plurality of capacitors exceeding a second threshold value for more than a second threshold period of time, or both, open the pre-charge switch and the bypass switch to prevent the current from flowing into the plurality of capacitors and the pre-charge circuit.

12. The industrial automation system of claim 11, wherein the one or more of the plurality of respective voltages of the plurality of capacitors exceeding the second threshold value for more than the second threshold period of time is indicative of a fault within the drive module.

13. The industrial automation system of claim 11, wherein the drive module comprises:
a capacitor voltage sensing circuit configured to monitor the plurality of respective voltages of the plurality of capacitors and output a first signal indicative of one or more of the plurality of respective voltages of the plurality of capacitors; and
a main control board configured to receive the first signal and provide a second signal to the pre-charge protection circuit to open the pre-charge switch and the bypass switch to prevent the current from flowing from the power source into the plurality of capacitors and the pre-charge circuit in response to the one or more of the plurality of respective voltages of the plurality of capacitors exceeding the second threshold value for more than the second threshold period of time.

14. The industrial automation system of claim 13, wherein the pre-charge protection circuit comprises a capacitor overvoltage signal circuit configured to:
receive the first signal from the capacitor voltage sensing circuit; and
output a third signal to open the pre-charge switch and the bypass switch to prevent the current from flowing from the power source into the plurality of capacitors and the pre-charge circuit in response to the one or more of the plurality of respective voltages of the plurality of capacitors exceeding the second threshold value for more than the second threshold period of time.

15. The industrial automation system of claim 11, wherein the pre-charge protection circuit comprises:
a control power circuit configured to receive an input voltage and provide power to the pre-charge protection circuit based on the input voltage;
a pre-charge input voltage sensing circuit configured to output a first signal indicative of a voltage across the pre-charge circuit, wherein the voltage across the pre-charge circuit comprises a difference between the input voltage to the pre-charge circuit and an output voltage of the pre-charge circuit;
a pre-charge protection control circuit configured to receive, from the pre-charge input voltage sensing circuit, the first signal indicative of the voltage across the pre-charge circuit, in response to the voltage across the pre-charge circuit being below the threshold value, outputting a second signal to allow the current to flow from the power source into one or more of the plurality of capacitors, and in response to the voltage across the pre-charge circuit being above the threshold value for more than a third threshold period of time, outputting a third signal to prevent the current from flowing from the power source into the one or more of the plurality of capacitors; and
a pre-charge bypass signal circuit configured to receive the second and third signals from the pre-charge protection control circuit, and output a fourth signal to enable or disable the bypass switch based on receiving the second signal or the third signal.

16. A method, comprising:
monitoring a voltage across a pre-charge circuit of a drive module disposed within an industrial automation system, wherein the pre-charge circuit is configured to reduce current flowing from a power source to a plurality of capacitors when the drive module is powered on;
identifying when the voltage across the pre-charge circuit exceeds a threshold value for more than a threshold period of time; and
in response to the voltage across the pre-charge circuit exceeding the threshold value for more than the threshold period of time, opening a pre-charge switch and a pre-charge bypass switch to prevent current from flowing from the power source into the pre-charge circuit and the plurality of capacitors of the drive module.

17. The method of claim 16, comprising:
monitoring a plurality of respective voltages of the plurality of capacitors of the drive module disposed within the industrial automation system;
identifying when one or more of the plurality of respective voltages of the plurality of capacitors exceeds an additional threshold value for more than an additional threshold period of time; and
in response to the one or more of the plurality of respective voltages of the plurality of capacitors exceeding the additional threshold value for more than the additional threshold period of time, opening the pre-charge switch and the bypass switch to prevent the current from flowing from the power source into the plurality of capacitors and the pre-charge circuit.

18. The method of claim 17, comprising:
receiving, via a main circuit board, from a capacitor voltage sensing circuit, a first signal indicative of one or more of the plurality of respective voltages of the plurality of capacitors; and
providing a second signal to open the pre-charge switch and the bypass switch to prevent the current from flowing from the power source into the plurality of capacitors and the pre-charge circuit in response to one or more of the plurality of respective voltages of the plurality of capacitors exceeding the additional threshold value for more than the additional threshold period of time.

19. The method of claim 18, comprising:
receiving, via a capacitor overvoltage signal circuit, the first signal from the capacitor voltage sensing circuit; and
outputting, via the capacitor overvoltage signal circuit, a third signal to open the pre-charge switch and the bypass switch to prevent the current from flowing from the power source into the plurality of capacitors and the pre-charge circuit in response to the one or more of the plurality of respective voltages of the plurality of capacitors exceeding the additional threshold value for more than the additional threshold period of time.

20. The method of claim 16, comprising:
receiving, via a control power circuit, an input voltage;
providing, via the control power circuit, power based on the input voltage;
outputting, via a pre-charge input voltage sensing circuit, a first signal indicative of a voltage across the pre-charge circuit, wherein the voltage across the pre-charge circuit comprises a difference between the input voltage to the pre-charge circuit and an output voltage of the pre-charge circuit;
receiving, from the pre-charge input voltage sensing circuit, the first signal indicative of the voltage across the pre-charge circuit;
in response to the voltage across the pre-charge circuit being below the threshold value, outputting a second signal to allow the current to flow from the power source into one or more of the plurality of capacitors;
in response to the voltage across the pre-charge circuit being above the threshold value for more than the threshold period of time, outputting a third signal to prevent the current from flowing from the power source into the one or more of the plurality of capacitors;
receiving the second and third signals from a pre-charge protection control circuit; and
outputting a fourth signal to enable or disable the bypass switch based on receiving the second signal or the third signal.
